(19) United States
(12) Patent Application Publication
(10) Pub. No.: US 2010/0201250 A1
(43) Pub. Date: Aug. 12, 2010

(54) METHOD OF PRODUCING ILLUMINANTS CONSISTING OF ORTHOSILICATES FOR pcLEDs

(76) Inventors: Holger Winkler, Darmstadt (DE); Tim Vosgroene, Ober-Ramstadt (DE); Gundula Roth, Levenhagen (DE); Walter Tews, Greifswald (DE); Stefan Tews, Greifswald (DE)

Correspondence Address: MILLEN, WHITE, ZELANO & BRANIGAN, P.C., 2200 CLARENDON BLVD., SUITE 1400, ARLINGTON, VA, 22201, US

(21) Appl. No.: 12/594,497

(22) PCT Filed: Mar. 5, 2008
(86) PCT No.: PCT/EP08/01743

§ 371 Date: Apr. 15, 2010

(30) Foreign Application Priority Data
Apr. 4, 2007 (DE) 10 2007 016 229.6

(51) Int. Cl. H01J 1/62; F21V 9/16; H01L 51/54; C09K 11/77

(52) U.S. Cl. 313/486; 313/483; 313/503; 362/84; 313/504; 252/301.4 R

(57) ABSTRACT

The invention relates to a process for the preparation of phosphors of the formula I

Ba_{w}SrₓCa_{y}SiO₄:zEu²⁺ (I)

where
w+x+y+z=2 and
0.005≦z≦0.5,
and to an illumination unit and to the use of the phosphor as LED conversion phosphor for white LEDs or so-called colour-on-demand applications.

The invention relates to a wet-chemical process for the preparation of phosphors which consist of europium(II)-doped orthosilicates, preferably alkaline-earth metal orthosilicates, and to the use thereof as LED conversion phosphor for white LEDs or so-called colour-on-demand applications.

The colour-on-demand concept is taken to mean the production of light of a certain colour location by means of a pcLED using one or more phosphors. This concept is used, for example, in order to produce certain corporate designs, for example for illuminated company logos, trademarks, etc.

Recently, phosphors which emit blue-green light, yellow-green to orange light based on excitation in the UV light region or blue light region of the optical spectrum have become ever more important. This is due to the fact that the phosphors can be used for equipment emitting white light. In particular, cerium-doped garnet phosphors (YAG:Ce) are being used in various ways (see, for example, EP 862794, WO 98/12757). However, these have the disadvantage that they only have sufficiently high efficiency at an emission maximum below 560 nm. For this reason, pure YAG:Ce phosphors in combination with blue diodes (450-490 nm) can only be used for the production of cold-white light colours having colour temperatures between 6000 and 8000 K and having comparatively low colour reproduction (typical values for the colour reproduction index Ra are between 70 and 75). This gives rise to greatly restricted application potential. On the one hand, higher demands are generally made of the colour reproduction quality of the lamp on use of white light sources in general lighting, and on the other hand warmer light colours having colour temperatures between 2700 and 5000 K are preferred by consumers, especially in Europe and North America.

WO 00/33389 furthermore discloses the use of, inter alia, Ba₂SiO₄:Eu²⁺ as luminophore for conversion of the light from blue LEDs. However, the maximum of the phosphor emission is at 505 nm, meaning that it is not possible reliably to produce white light using a combination of this type.

Silicate phosphors have been developed in preceding years for white LEDs (see WO 02/11214, WO 02/054502). It is furthermore known that these phosphors can be used for gas discharge lamps (see K. H. Butler “Fluorescent Lamp Phosphors” Pennsylvania Univ. Press, 1980). In addition, T. L. Barry, J. Electrochem. Soc. 1968, 1181, describes that homogeneous, solid, binary mixtures of (Ca,Sr)₂SiO₄:Eu have been systematically researched. These phosphors were prepared by the solid-state diffusion method (mixing & firing method) by mixing oxidic starting materials as powders, grinding the mixture and then calcining the ground powders in a furnace at temperatures up to 1500° C. for up to several days in an optionally reducing atmosphere. As a result, phosphor powders are formed which have inhomogeneities with respect to the morphology, the particle size distribution and the distribution of the luminescent activator ions in the volume of the matrix. Furthermore, the morphology, the particle size distributions and other properties of these phosphors prepared by the traditional process can only be adjusted with difficulty and are hard to reproduce. These particles therefore have a number of disadvantages, such as, in particular, an inhomogeneous coating of the LED chip with these phosphors having non-optimum and inhomogeneous morphology and particle size distribution, which result in high loss processes due to scattering. Further losses occur in production of these LEDs through the fact that the phosphor coating of the LED chip is not only inhomogeneous, but is also not reproducible from LED to LED. This results in variations of the colour locations of the emitted light from the pcLEDs also occurring within a batch. The LED silicate phosphors are used individually or in a mixture for a blue or UV LED matrix in order to obtain a higher CRI than the YAG:Ce series. In practice, however, the conventional silicate phosphors do not exhibit higher efficiency and illuminance than the YAG:Ce phosphors. In addition, it is reported (see T. L. Barry, J. Electrochem. Soc. 1968, 1181) that some phosphors having a high barium concentration have a problem with hydrolysis sensitivity during use. These deficiencies result in reduced efficiency of the silicate phosphors.

DE 10 2005051063 A1 discloses a silicate-based phosphor having improved emission efficiency which was prepared by wet-chemical methods (wet-grinding and wet-sieving methods) using a nonaqueous organic solvent, such as, for example, ethanol, in order to remove most of the water left in a purification process.

The object of the present invention is therefore to provide a process for the preparation of alkaline-earth metal orthosilicate phosphors for white LEDs or for colour-on-demand applications which do not have one or more of the above-mentioned disadvantages and produce warm-white light.

Surprisingly, this object is achieved by preparing the alkaline-earth metal orthosilicate phosphors by a wet-chemical process, where two process variants are possible.

The present invention thus relates to a process for the preparation of phosphors of the formula I

Ba_{w}SrₓCa_{y}SiO₄: zEu²⁺ (I)

where
w+x+y+z=2 and
0.005<z<0.5,
characterised in that
a) at least two alkaline-earth metals and a europium-containing dopant and a silicon-containing compound in the form of salts, nitrates, oxalates, hydroxides or mixtures thereof are dissolved, suspended or dispersed in water, acids or bases,
b) this mixture is sprayed in a heated pyrolysis reactor and converted into the phosphor precursor by thermal decomposition and
c) subsequently converted into the finished phosphor by thermal after-treatment.
   w, x, y or z here can adopt values between 0 and 2.

The electrically heated pyrolysis reactor employed is preferably a spray pyrolysis reactor, such as, for example, a hot-wall reactor (Merck in-house design). In order to carry out the process according to the invention, the solutions, dispersions or suspensions prepared in advance are sprayed into an externally electrically heated tube by means of a two-component nozzle with a defined air/feed ratio. The principle is illustrated in the drawing in FIG. 1. The powder is separated from the hot-gas stream with the aid of a porous metal filter. The requisite reduced energy input immediately after the spray-in point is achieved automatically in this reactor through the cooling effect as a consequence of solvent evaporation and the low turbulence of the flow.

The reactor temperature in the spray pyrolysis reactor is between 600 and 1080° C., preferably between 800 and 1000° C. Additional energy is introduced in accordance with the invention by a chemical decomposition reaction of inorganic salts, for example chlorides, preferably ammonium chloride, or nitrate or chlorate in an amount of 0.5 to 80%, preferably 1 to 5%, based on the amount of starting material employed. These inorganic salts serve as fluxing agents for lowering the melting point and are added before or during the thermal aftertreatment.

The alkaline-earth metal starting materials employed are preferably barium, strontium and/or calcium nitrate in the desired stoichiometric ratio.

Instead of a spray pyrolysis reactor or hot-wall reactor, the pyrolysis reactor used can also be a pulsation reactor. Patent application DE 10 2006027133.5 by Merck (date of filing: Dec. 6, 2006), which is incorporated into the context of the present application in its full scope by way of reference, describes in detail how garnet phosphors can be prepared by a specific process design in a pulsation reactor. The phosphors of the formula I according to the invention can be prepared analogously by this pulsation reactor process, where the starting solutions are sprayed into a hot-gas stream generated by pulsating, flameless combustion.

The present invention furthermore relates to a process for the preparation of a phosphor of the formula I mentioned above, characterised in that
a) at least two alkaline-earth metals and a europium-containing dopant in the form of salts, nitrates, oxalates, hydroxides or mixtures thereof are dissolved, suspended or dispersed in water, acids or bases, and
b) a silicon-containing compound is added at elevated temperature, and
c) this mixture is spray-dried at temperatures <300° C. and
d) subsequently converted into finished phosphors by thermal after-treatment.

The alkaline-earth metal starting materials employed in this process variant are preferably barium, strontium and/or calcium hydroxide in the desired stoichiometric ratio.

Suitable silicon-containing compounds in both process variants are generally inorganic or organic silicon compounds. In accordance with the invention, preference is given to the use of silicon dioxide or tetraethyl orthosilicate.

In the last-mentioned process variant, the silicon-containing compound is added to the mixture of alkaline-earth metal salts and dopant at temperatures between 25 and 95° C., preferably between 75 and 90° C. This is followed by spray drying in a GEA Niro spray tower at temperatures between 200 and 350° C., preferably between 250 and 300° C. The nozzle pressure in the spray tower is between 1 and 3 bar, preferably 2 bar. The amount of sprayed solution as a function of time is between 2 and 6 litres of reaction solution per hour, preferably 4 litres per hour.

Dopants which can be employed are generally any desired europium salts, where europium nitrate and europium chloride are preferred. It is furthermore preferred for the doping concentration of the europium to be between 0.5 and 50 mol %. It is particularly preferably between 2.0 and 20 mol %. At a europium concentration between 10 and 15 mol %, increased absorption and consequently an increased light yield or greater brightness of the phosphor generally arise. A higher europium concentration would reduce the quantum yield and thus in turn result in a reduced light yield.

The thermal aftertreatment of the phosphor precursor to give the finished phosphor is carried out in a high-temperature furnace by calcination of a defined amount of precursor for a number of hours at temperatures between 1000 and 1400° C. in corundum crucibles. The crude phosphor cake is comminuted, washed and sieved.

In the above-mentioned thermal aftertreatment, it is preferred for the calcination to be carried out at least partially under reducing conditions (for example using carbon monoxide, forming gas or hydrogen or at least a vacuum or oxygen-deficiency atmosphere).

The particle size of the phosphors according to the invention is between 50 nm and 50 μm, preferably between 1 μm and 25 μm.

In a further process variant, it is preferred in accordance with the invention for the surface of the phosphor additionally to be structured, for example by means of a pyramidal structure (see DE 102006054330.0, Merck, which is incorporated into the context of the present application in its full scope by way of reference). This enables as much light as possible to be coupled out of the phosphor.

The structured surface on the phosphor is produced by subsequent coating with a suitable material which has already been structured, or in a subsequent step by (photo)lithographic processes, etching processes or by writing processes using energy or material beams or the action of mechanical forces.

In a further process variant, it is preferred in accordance with the invention for a rough surface which carries nanoparticles of SiO₂, TiO₂, Al₂O₃, ZnO₂, ZrO₂ and/or Y₂O₃ or combinations of these materials or of particles comprising the phosphor composition to be produced on the side opposite an LED chip.

A rough surface here has a roughness of up to a few 100 nm. The coated surface has the advantage that total reflection can be reduced or prevented and the light can be coupled out of the phosphor according to the invention better (see DE 102006054330.0 (Merck), which is incorporated into the context of the present application in its full scope by way of reference).

It is furthermore preferred for the phosphors prepared by the process according to the invention to have a refractive-index-adapted layer on the surface facing away from the chip, which simplifies the coupling-out of the primary radiation and/or the radiation emitted by the phosphor element.

In a further process variant, it is preferred in accordance with the invention for the surface of the phosphor additionally to be provided with a closed coating of SiO₂, TiO₂, Al₂O₃, ZnO, ZrO₂ and/or Y₂O₃ or mixed oxides thereof. This surface coating has the advantage that adaptation of the refractive index to the environment can be achieved through a suitable graduation of the refractive indices of the coating materials. In this case, scattering of the light at the surface of the phosphor is reduced and a greater proportion of the light can penetrate into the phosphor and be absorbed and converted there. In addition, the refractive-index-adapted surface coating enables more light to be coupled out of the phosphor since total internal reflection is reduced.

In addition, a closed layer is advantageous if the phosphor has to be encapsulated. This may be necessary in order to counter sensitivity of the phosphor or parts thereof to diffusing water or other materials in the direct vicinity. A further reason for encapsulation with a closed sheath is thermal decoupling of the actual phosphor from the heat formed in the chip. This heat results in a reduction in the fluorescence light yield of the phosphor and can also affect the colour of the fluorescent light. Finally, a coating of this type enables the efficiency of the phosphor to be increased by preventing lattice vibrations forming in the phosphor from propagating into the environment.

In addition, it is preferred for phosphors having a porous surface coating consisting of SiO₂, TiO₂, Al₂O₃, ZnO, ZrO₂ and/or Y₂O₃ or mixed oxides thereof or of the phosphor composition to be prepared by the process. These porous coatings offer the possibility of further reducing the refractive index of a single layer. Porous coatings of this type can be produced by three conventional methods, as described in WO 03/027015, which is incorporated into the context of the present application in its full scope by way of reference: the etching of glass (for example soda-lime glasses (see U.S. Pat. No. 4,019,884)), the application of a porous layer, and the combination of a porous layer and an etching process.

In a further preferred process variant, phosphors having a surface which carries functional groups which facilitate chemical bonding to the environment, preferably consisting of epoxy or silicone resin, are prepared. These functional groups may be esters or other derivatives which are bonded, for example, via oxo groups and are able to form links to constituents of the binders based on epoxides and/or silicones. Surfaces of this type have the advantage that homogeneous mixing of the phosphors into the binder is facilitated. Furthermore, the rheological properties of the phosphor/binder system and also the pot lives can consequently be adjusted to a certain extent. Processing of the mixtures is thus simplified.

Since the phosphor layer according to the invention applied to the LED chip preferably consists of a mixture of silicone and homogeneous phosphor particles, and the silicone has a surface tension, this phosphor layer is non-uniform at a microscopic level, or the thickness of the layer is not constant throughout.

The present invention furthermore relates to a phosphor of the formula I

Ba_{w}SrₓCa_{y}SiO₄:zEu²⁺ (I)

where
w+x+y+z=2 and
0.005<z<0.5,
prepared by the process according to the invention. This phosphor preferably has a structured surface or a rough surface carrying nanoparticles of SiO₂, TiO₂, Al₂O₃, ZnO, ZrO₂ and/or Y₂O₃ or mixed oxides thereof or of particles comprising the phosphor composition.

It is furthermore preferred for this phosphor of the formula 1 to have a closed or alternatively porous surface coating consisting of SiO₂, TiO₂, Al₂O₃, ZnO, ZrO₂ and/or Y₂O₃ or mixed oxides thereof. It may furthermore be preferred for the surface of the phosphor to carry functional groups which facilitate chemical bonding to the environment, preferably comprising epoxy or silicone resin.

With the aid of the above-mentioned processes, any desired outer shapes of the phosphor particles can be produced, such as spherical particles, flakes and structured materials and ceramics.

As a further preferred embodiment, flake-form phosphors are prepared by conventional processes from the corresponding alkaline-earth metal salts and europium salts. The preparation process is described in detail in EP 763573 and DE 102006054331.9, which are incorporated into the context of the present application in their full scope by way of reference. These flake-form phosphors can be prepared by coating a natural or synthetically produced, highly stable support or a substrate of, for example, mica flakes, SiO₂ flakes, Al₂O₃ flakes, ZrO₂ flakes, glass flakes or TiO₂ flakes which has a very large aspect ratio, an atomically smooth surface and an adjustable thickness with a phosphor layer by a precipitation reaction in aqueous dispersion or suspension. Besides mica, ZrO₂, SiO₂, Al₂O₃, glass or TiO₂ or mixtures thereof, the flakes may also consist of the phosphor material itself or be built up from a material. If the flake itself serves merely as support for the phosphor coating, the latter must consist of a material which is transparent to the primary radiation from the LED, or absorbs the primary radiation and transmits this energy to the phosphor layer. The flake-form phosphors are dispersed in a resin (for example silicone or epoxy resin), and this dispersion is applied to the LED chip.

The flake-form phosphors can be prepared on a large industrial scale in thicknesses of 50 nm to about 300 μm, preferably between 150 nm and 100 μm. The diameter here is from 50 nm to 20 μm.

It generally has an aspect ratio (ratio of the diameter to the particle thick-ness) from 1:1 to 400:1 and in particular 3:1 to 100:1.

The flake size (length x width) is dependent on the arrangement. Flakes are also suitable as centres of scattering within the conversion layer, in particular if they have particularly small dimensions.

The surface of the flake-form phosphor according to the invention facing the LED chip can be provided with a coating which has a reflection-reducing action in relation to the primary radiation emitted by the LED chip. This results in a reduction in back-scattering of the primary radiation, enhancing coupling of the latter into the phosphor element according to the invention.

Suitable for this purpose are, for example, refractive-index-adapted coatings, which must have a following thickness d:d=[wavelength of the primary radiation from the LED chip/(4* refractive index of the phosphor ceramic)], see, for example, Gerthsen, Physik [Physics], Springer Verlag, 18th Edition, 1995. This coating may also consist of photonic crystals, which also encompasses structuring of the surface of the flake-form phosphor in order to achieve certain functionalities. This enables as much light as possible to be coupled out of the phosphor element. The structured surface on the phosphor element is produced by carrying out the isostatic pressing using a mould having a structured press plate and thus embossing a structure into the surface. Structured surfaces are desired if the aim is to produce the thinnest possible phosphor elements or flakes. The pressing conditions are known to the person skilled in the art (see J. Kriegsmann, Technische keramische Werkstoffe [Industrial Ceramic Materials], Chapter 4, Deutscher Wirtschaftsdienst, 1998). It is important that the pressing temperatures used are ⅔ to ⅚ of the melting point of the substance to be pressed.

In addition, the phosphors according to the invention can be excited over a broad range, which extends from about 120 nm to 530 nm, preferably 254 nm to about 480 nm. These phosphors are thus not only suitable for excitation by UV or blue-emitting primary light sources, such as LEDs, or conventional discharge lamps (for example based on Hg), but also for light sources like those which utilise the blue In³⁺ line at 451 nm.

The present invention furthermore relates to an illumination unit having at least one primary light source whose emission maximum or maxima is or are in the range 120 nm to 530 nm, preferably 254 nm to about 480 nm, where the primary radiation is partially or fully converted into longer-wave-length radiation by the phosphors according to the invention.

In accordance with the invention, the term “illumination unit” encompasses the following components or constituents:
at least one primary light source for emitting ultraviolet or blue light,
at least one conversion phosphor which is located in direct or indirect contact with a primary light source,
optionally a transparent sealing resin (for example epoxy or silicone resin) for encapsulation of the illumination unit,
optionally a support component on which the primary light source is mounted and which has at least two electrical connections for the supply of electrical energy for the primary light source,
optionally secondary optical arrangements, such as lenses, mirrors, prisms or photonic crystals.

This illumination unit preferably emits white light or emits light having a certain colour location (colour-on-demand principle). Preferred embodiments of the illumination units according to the invention are described in FIGS. 4 to 15.

In a preferred embodiment of the illumination unit according to the invention, the light source is a luminescent indium aluminium gallium nitride, in particular of the formula InᵢGaⱼAlₖN, where 0≦i, 0≦j, 0≦k, and i+j+k=1. Possible forms of light sources of this type are known to the person skilled in the art. They can be light-emitting LED chips having various structures.

In a further preferred embodiment of the illumination unit according to the invention, the light source is a luminescent arrangement based on ZnO, TCO (transparent conducting oxide), ZnSe or SiC or an arrangement based on an organic light-emitting layer (OLED).

In a further preferred embodiment of the illumination unit according to the invention, the light source is a source which exhibits electroluminescence and/or photoluminescence. The light source may furthermore also be a plasma or discharge source.

The phosphors according to the invention can either be dispersed in a resin (for example epoxy or silicone resin) or, given suitable size ratios, arranged directly on the primary light source or, depending on the application, arranged remote therefrom (the latter arrangement also includes “remote phosphor technology”). The advantages of remote phosphor technology are known to the person skilled in the art and are revealed, for example, in the following publication: Japanese Journ. of Appl. Phys. Vol 44, No. 21 (2005). L649-L651.

In a further embodiment, it is preferred for the optical coupling of the illumination unit between the phosphor and the primary light source to be achieved by a light-conducting arrangement. This enables the primary light source to be installed at a central location and to be optically coupled to the phosphor by means of light-conducting devices, such as, for example, light-conducting fibres. In this way, lamps matched to the illumination wishes and merely consisting of one or different phosphors, which may be arranged to form a light screen, and one or more light conductors, which are coupled to the primary light source, can be achieved. In this way, it is possible to position a strong primary light source at a location which is favourable for the electrical installation and to install lamps comprising phosphors which are coupled to the light conductors at any desired locations without further electrical cabling, but instead only by laying light conductors.

It is furthermore preferred in accordance with the invention for the primary light source, which emits light in the vacuum UV (<200 nm) and/or UV region, to have, in combination with the phosphor according to the invention, an emission band having a half-value width of at least 10 nm.

The present invention furthermore relates to the use of the phosphors according to the invention for partial or complete conversion of the blue or near-UV emission from a luminescent diode.

The phosphors according to the invention are furthermore preferably used for conversion of the blue or near-UV emission into visible white radiation. The phosphors according to the invention are furthermore preferably used for conversion of the primary radiation into a certain colour location in accordance with the “colour-on-demand” concept.

The present invention furthermore relates to the use of the phosphors according to the invention in electroluminescent materials, such as, for example, electroluminescent films (also known as lighting films or light films), in which, for example, zinc sulfide or zinc sulfide doped with Mn²⁺, Cu⁺ or Ag⁺ is employed as emitter, which emit in the yellow-green region. The areas of application of the electroluminescent film are, for example, advertising, display backlighting in liquid-crystal display screens (LC displays) and thin-film transistor (TFT) displays, self-illuminating vehicle licence plates, floor graphics (in combination with a crush-resistant and slip-proof laminate), in display and/or control elements, for example in automobiles, trains, ships and aircraft, or also domestic appliances, garden equipment, measuring instruments or sport and leisure equipment.

The following examples are intended to illustrate the present invention. However, they should in no way be regarded as limiting. All compounds or components which can be used in the compositions are either known and commercially available or can be synthesised by known methods. The temperatures indicated in the examples are always given in ° C. It furthermore goes without saying that, both in the description and also in the examples, the added amounts of the components in the compositions always add up to a total of 100%. Percentage data given should always be regarded in the given connection. However, they usually always relate to the weight of the part-amount or total amount indicated.

### EXAMPLES

### Example 1

### Preparation of the Phosphor Ba_{0.345}Sr_{1.6}Eu_{0.055}SiO₄ in a Hot-Wall Reactor

90.162 g of barium nitrate (analytical grade from Merck KGaA), 338.605 g of strontium nitrate (analytical grade from Merck KGaA), 60.084 g of highly disperse silicon dioxide (extra pure grade, Ph Eur, NF, E 551, Merck KGaA), 13.373 g of ammonium chloride (analytical grade from Merck KGaA) and 24.528 g of europium nitrate hexahydrate (analytical grade ACS, Treibacher Industrie AG) are dissolved or suspended in 5l of deionised water. The reaction solution is then sprayed into a hot-wall reactor with a length of 1.5 m by means of a two-component nozzle. The phosphor particles are separated from the hot-gas stream by means of sintered metal hot-gas filters.

Alternatively, the silicon source employed can also be tetraethyl orthosilicate (TEOS). In this example, the silicon dioxide described above is replaced with 208.33 g of TEOS (synthesis grade, Merck KGaA). In order to increase the solubility thereof in the reaction solution, some of the solvent water can be replaced with ethanol. However, it must be taken into account on use of TEOS or ethanol as solvent that additional energy is input into the system here, which may require correction of the heating parameters.

Hot-wall reactor settings:
Temperature: 800° C.
Nozzle pressure: 3 bar (N₂), countercurrent principle
Nozzle diameter: 1 mm
Throughput: 1.4 dm³ of solution/h
Separation in a sintered metal filter cartridge: Δp=50 mbar
Yield: 250 g (theoretical yield: 279 g)

### Example 2

### Preparation of the Phosphor Ba_{0.345}Sr_{1.6}Eu_{0.055}SiO₄ in a Spray Dryer

275.914 g of barium hydroxide octahydrate (extra pure grade, Merck KGaA), 1062.480 g of strontium hydroxide octahydrate (extra pure grade, Merck KGaA) and 50.369 g of europium chloride hexahydrate (analytical grade ACS, Treibacher Industrie AG) are suspended in 5 l of deionised water in a 20 l reactor using a precision glass stirrer and heated to 90° C. When all the material is suspended, 150.0 g of highly disperse silicon dioxide (extra pure grade, Ph Eur, NF, E 551, Merck KGaA) are added, and the mixture is rinsed with about 5 l of deionised water for this purpose. The reaction solution is subsequently spray-dried.

Spray tower settings (GEA Niro)
Nozzle pressure: 2 bar
Entry temperature: 250° C.
Exit temperature: 68 to 70° C.
Hose pump: 25 RPM (corresponds to about 4 l/h)

The precursors from Examples 1 and 2 are then converted into the phosphors in a calcination process at 1200° C. which takes place in a reducing forming-gas atmosphere. To this end, the precursors are introduced into a 250 ml corundum crucible, covered with 1-10% by weight, in a preferred embodiment with 5% by weight, of ammonium chloride, compacted by shaking and subsequently calcined for 5 hours. The finished crude phosphor cake is subsequently ground in a mortar mill, then washed, dried (T=120° C.) and sieved.

### DESCRIPTION OF THE FIGURES

The invention will be explained in greater detail below with reference to a number of illustrative embodiments. FIGS. 4 to 15 describe various illumination units, all of which contain the orthosilicate phosphors according to the invention:

FIG. 1: Sketch of the principle of a hot-wall reactor In order to carry out the process according to the invention, the solutions or dispersions prepared in advance are sprayed into an externally electrically heated tube by means of a two-component nozzle with a defined air/feed ratio. The principle is illustrated as a sketch in FIG. 1. The powder is separated from the hot-gas stream with the aid of a porous metal filter (1=solution or dispersion; 2=air; 3=two-component nozzle; 4=reactor tube; 5=heater; 6=flow source)

FIG. 2: Excitation spectrum of the phosphor Ba_{0.345}Sr_{1.6}Eu_{0.055}SiO₄

FIG. 3: Emission spectrum of the phosphor Ba_{0.345}Sr_{1.6}Eu_{0.055}SiO₄ on excitation at 465 nm.

FIG. 4: shows a diagrammatic drawing of a light-emitting diode with a phosphor-containing coating. The component includes a chip-like light-emitting diode (LED) 1 as radiation source. The light-emitting diode is installed in a cup-shaped reflector, which is held by an adjustment frame 2. The chip 1 is connected to a first contact 6 via a flat cable 7 and directly to a second electrical contact 6′. A coating comprising a conversion phosphor according to the invention has been applied to the inner curvature of the reflector cup. The phosphors are either employed separately from one another or in the form of a mixture. (List of part numbers: 1 light-emitting diode, 2 reflector, 3 resin, 4 conversion phosphor, 5 diffuser, 6 electrodes, 7 flat cable)

FIG. 5: shows a COB (chip on board) package of the InGaN type, which serves as light source (LED) for white light (1=semiconductor chip; 2,3=electrical connections; 4=conversion phosphor; 7=board). The phosphor is distributed in a binder lens, which simultaneously represents a secondary optical element and influences the light emission characteristics as a lens.

FIG. 6: shows a COB (chip on board) package of the InGaN type, which serves as light source (LED) for white light (1=semiconductor chip; 2,3=electrical connections; 4=conversion phosphor; 7=board). The phosphor is located in a thin binder layer distributed directly on the LED chip. A secondary optical element consisting of a transparent material can be placed thereon.

FIG. 7: shows a type of package which serves as light source (LED) for white light (1=semiconductor chip; 2,3=electrical connections; 4=conversion phosphor in cavity with reflector). The conversion phosphor is dispersed in a binder, with the mixture filling the cavity.

FIG. 8: shows a second type of package, where 1=housing plate; 2=electrical connections; 3=lens; 4=semiconductor chip. This design has the advantage of being a flip-chip design, where a greater proportion of the light from the chip can be used for light purposes via the transparent substrate and a reflector on the base. In addition, heat dissipation is favoured in this design.

FIG. 9: shows a package, where 1=housing plate; 2=electrical connections; 4=semiconductor chip, and the cavity beneath the lens is completely filled with the conversion phosphor according to the invention. This package has the advantage that a greater amount of conversion phosphor can be used. The latter can also act as remote phosphor.

FIG. 10: shows an SMD package (surface mounted package), where 1=housing; 2,3=electrical connections; 4=conversion layer. The semiconductor chip is completely covered by the phosphor according to the invention. The SMD design has the advantage of having a small physical shape and thus fitting into conventional lights.

FIG. 11: shows a T5 package, where 1=conversion phosphor; 2=chip; 3,4=electrical connections; 5=lens with transparent resin. The conversion phosphor is located on the back of the LED chip, which has the advantage that the phosphor is cooled via the metallic connections.

FIG. 12: shows a diagrammatic drawing of a light-emitting diode, where 1=semiconductor chip; 2,3=electrical connections; 4=conversion phosphor; 5=bond wire, where the phosphor is applied in a binder as top globe. This shape of the phosphor/binder layer can act as secondary optical element and influence, for example, the light propagation.

FIG. 13: shows a diagrammatic drawing of a light-emitting diode, where 1=semiconductor chip; 2,3=electrical connections; 4=conversion phosphor; 5=bond wire, where the phosphor is applied as a thin layer dispersed in a binder. A further component acting as secondary optical element, such as, for example, a lens, can easily be applied to this layer.

FIG. 14: shows an example of a further application, as is already known in principle from U.S. Pat. No. 6,700,322. The phosphor according to the invention is used here together with an OLED. The light source is an organic light-emitting diode 31 consisting of the actual organic film 30 and a transparent substrate 32. The film 30 emits, in particular, blue primary light, produced, for example, by means of PVK:PBD:coumarin (PVK, abbreviation for poly-(n-vinylcarbazole); PBD, abbreviation for 2-(4-biphenyl)-5-(4-tert-butyl-phenyl)-1,3,4-oxadiazole). The emission is partially converted into yellow, secondarily emitted light by a cover layer, formed by a layer 33 of the phosphor according to the invention, producing overall white emission through colour mixing of the primarily and secondarily emitted light. The OLED essentially consists of at least one layer of a light-emitting polymer or of so-called small molecules between two electrodes, which consist of materials known per se, such as, for example, ITO (abbreviation for indium tin oxide), as anode and a highly reactive metal, such as, for example, Ba or Ca, as cathode. A plurality of layers are often also used between the electrodes, which either serve as hole-transport layer or, in the area of small molecules, also serve as electron-transport layers. The emitting polymers used are, for example, polyfluorenes or polyspiro materials.

FIG. 15: shows a low-pressure lamp 20 with a mercury-free gas filling 21 (diagrammatic), which comprises an indium filling and a buffer gas analogously to WO 2005/061659, where a layer 22 of the phosphors according to the invention is applied.

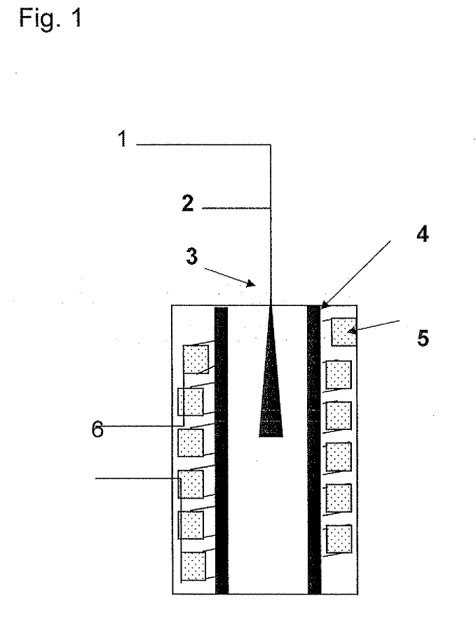

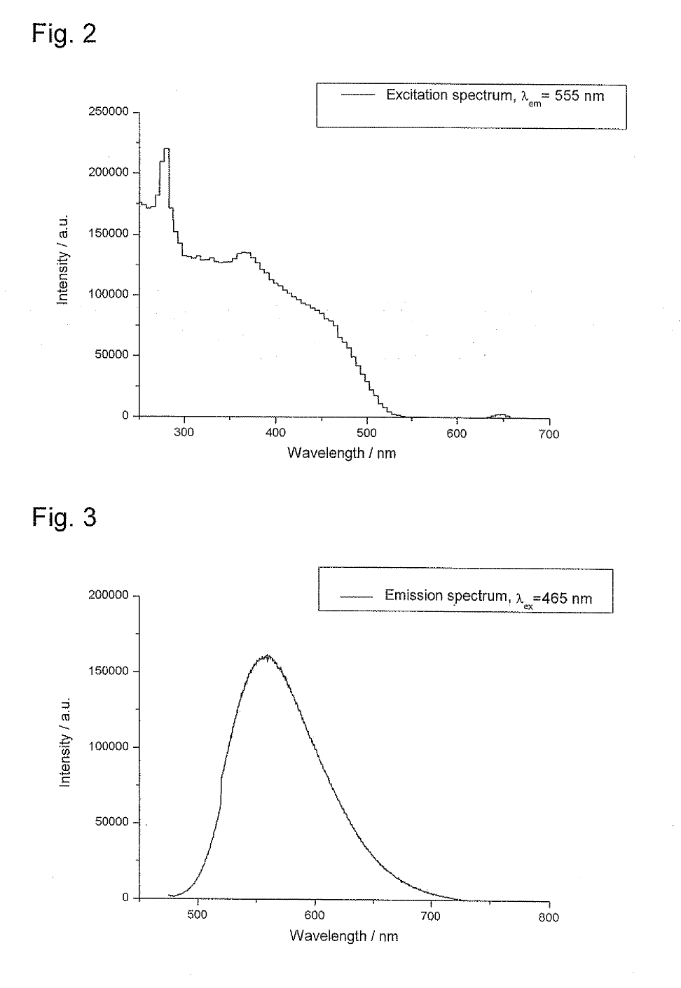

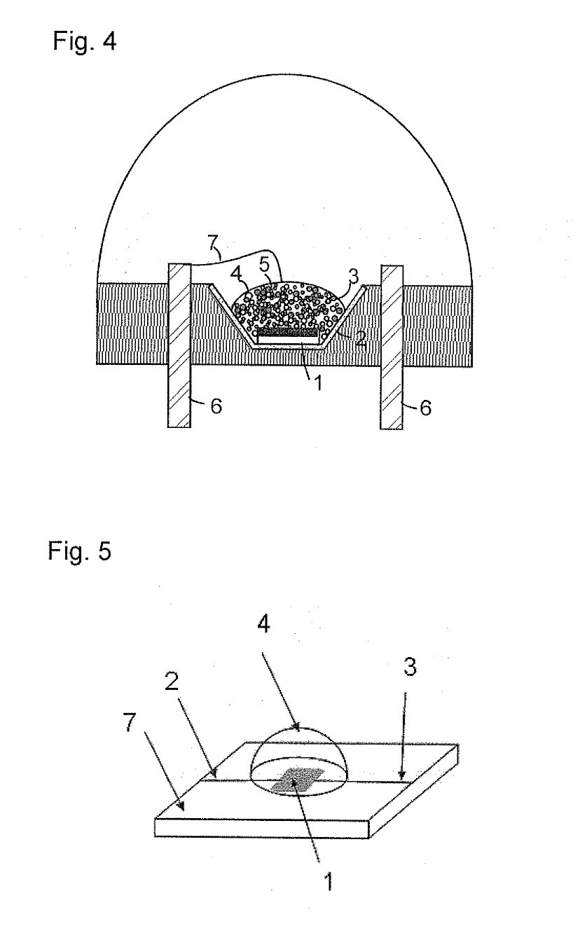

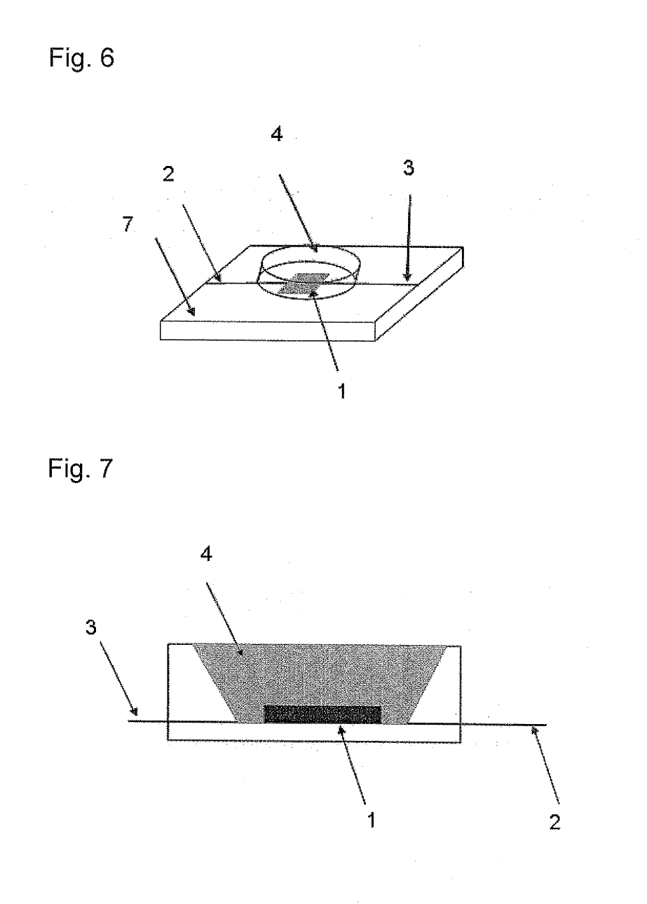

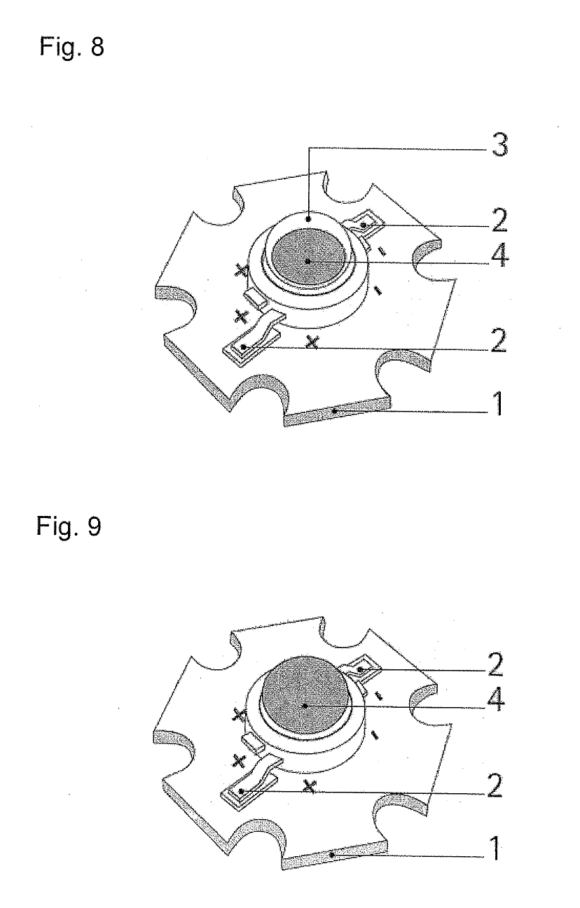

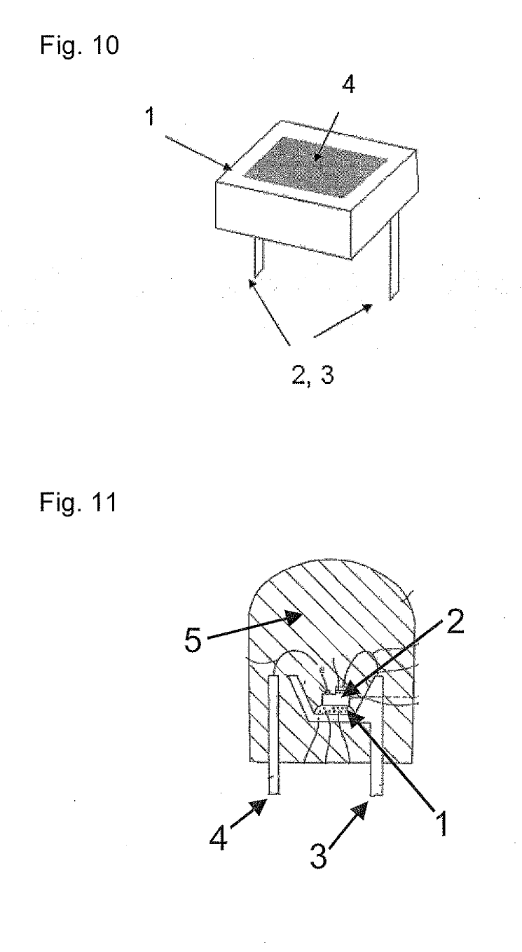

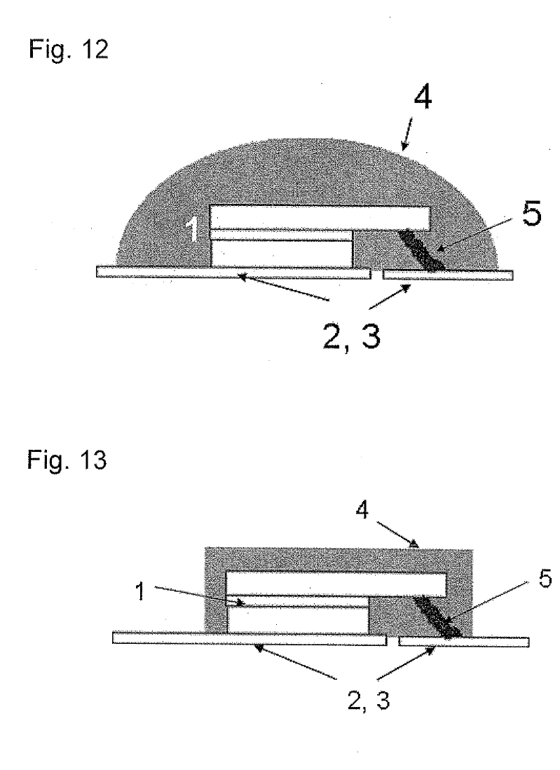

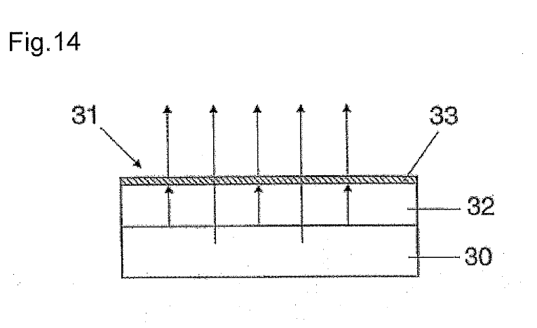

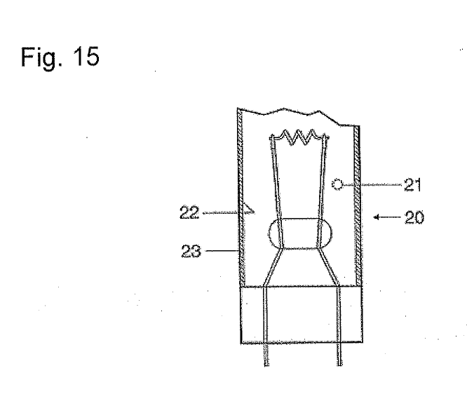

1. Process for the preparation of a phosphor of the formula I
Ba_{w}SrₓCa_{y}SiO₄:zEu²⁺ (I)
where
2. w+x+y+z=2,
3. 0.005<z<0.5,
4. characterised in that
b) at least two alkaline-earth metals and a europium-containing dopant and a silicon-containing compound in the form of salts, nitrates, oxalates, hydroxides or mixtures thereof are dissolved, suspended or dispersed in water, acids or bases,
c) this mixture is sprayed in a heated pyrolysis reactor and converted into the phosphor precursor by thermal decomposition and
d) subsequently converted into the finished phosphor by thermal aftertreatment.

2. Process for the preparation of a phosphor of the formula I
Ba_{w}SrₓCa_{y}SiO₄:zEu²⁺ (I)
where
w+x+y+z=2,
0.005<z<0.5,
characterised in that
a) at least two alkaline-earth metals and a europium-containing dopant in the form of salts, nitrates, oxalates, hydroxides or mixtures thereof are dissolved, suspended or dispersed in water, acids or bases, and
b) a silicon-containing compound is added at elevated temperature, and
c) this mixture is spray-dried at temperatures <300° C. and
d) subsequently converted into finished phosphors by thermal after-treatment.

3. Process according to claim 1 claim 1, characterised in that an inorganic salt is added as fluxing agent before or during the thermal aftertreatment.

4. Process according to claim 3, characterised in that the inorganic salt which decomposes in an exothermic reaction, selected from the group chloride, preferably ammonium chloride, or nitrate or chlorate, is added in an amount of 0.5 to 80%, preferably 1 to 5%, based on the amount of starting material employed.

5. Process according to claim 1, characterised in that the surface of the phosphor is additionally structured.

6. Process according to claim 1, characterised in that the phosphor is additionally provided with a rough surface which carries nanoparticles of SiO₂, TiO₂, Al₂O₃, ZnO, ZrO₂ and/or Y₂O₃ or mixed oxides thereof or particles comprising the phosphor composition.

7. Process according to claim 1, characterised in that the surface of the phosphor is additionally provided with a closed coating of SiO₂, TiO₂, Al₂O₃, ZnO, ZrO₂ and/or Y₂O₃ or mixed oxides thereof.

8. Process according to claim 1, characterised in that the surface of the phosphor is provided with a porous coating of SiO₂, TiO₂, Al₂O₃, ZnO, ZrO₂ and/or Y₂O₃ or mixed oxides thereof or of the phosphor composition.

9. Process according to claim 1, characterised in that the surface is additionally provided with functional groups which facilitate chemical bonding to the environment, preferably comprising epoxy or silicone resin.

10. Phosphor of the formula I
Ba_{w}SrₓCa_{y}SiO₄:zEu²⁺ (I)
where
w+x+y+z=2,
0.005<z<0.5,
prepared by a process according to one or more of claims 1 to 9 claim 1.

11. Phosphor according to claim 10, characterised in that it has a structured surface.

12. Phosphor according to claim 10 and/or 11, characterised in that it has a rough surface carrying nanoparticles of SiO₂, TiO₂, Al₂O₃, ZnO, ZrO₂ and/or Y₂O₃ or mixed oxides thereof or particles comprising the phosphor composition.

13. Phosphor according to claim 10 and/or 11, characterised in that it has a closed surface coating consisting of SiO₂, TiO₂, Al₂O₃, ZnO, ZrO₂ and/or Y₂O₃ or mixed oxides thereof.

14. Phosphor according to claim 10 and/or 11, characterised in that it has a porous surface coating consisting of SiO₂, TiO₂, Al₂O₃, ZnO, ZrO₂ and/or Y₂O₃ or mixed oxides thereof.

15. Phosphor according to claim 10, characterised in that the surface carries functional groups which facilitate chemical bonding to the environment, preferably consisting of epoxy or silicone resin.

16. Illumination unit having at least one primary light source whose emission maximum is in the range 120 to 530 nm, preferably between 254 nm and 480 nm, where this radiation is partially or fully converted into longer-wavelength radiation by a phosphor according to claim 10.

17. Illumination unit according to claim 16, characterised in that the light source is a luminescent indium aluminium gallium nitride, in particular of the formula InᵢGaⱼAlₖN, where 0≦i, 0≦j, 0≦k, and i+j+k=1.

18. Illumination unit according to claim 16, characterised in that the light source is a luminescent compound based on ZnO, TCO (transparent conducting oxide), ZnSe or SiC.

19. Illumination unit according to claim 16, characterised in that the light source is a material based on an organic light-emitting layer.

20. Illumination unit according to one or more of claim 16, characterised in that the light source is a source which exhibits electroluminescence and/or photoluminescence.

21. Illumination unit according to claim 16, characterised in that the light source is a plasma or discharge source.

22. Illumination unit according to claim 16, characterised in that the phosphor is arranged directly on the primary light source and/or remote therefrom.

23. Illumination unit according to claim 16, characterised in that the optical coupling between the phosphor and the primary light source is achieved by a light-conducting arrangement.

24. Illumination unit according to claim 16, characterised in that the primary light source, which emits light in the vacuum UV and/or UV and/or blue and/or green region of the visible spectrum, has, in combination with a phosphor according to Formula I, an emission band having a half-value width of at least 10 nm.

25. A method for partial or complete conversion of the blue or near-UV emission from a luminescent diode comprising using at least one phosphor of the formula I according to claim 10 as conversion phosphor.

26. A method for conversion of the primary radiation into a certain colour point in accordance with the colour-on-demand concept comprising using at least one phosphor of the formula I according to claim 10 as conversion phosphor.

27. A method for conversion of the blue or near-UV emission into visible white radiation comprising using at least one phosphor of the formula I according to claim 10.
